(19) United States
(12) Patent Application Publication
(10) Pub. No.: US 2025/0328079 A1
(43) Pub. Date: Oct. 23, 2025

(54) UV ASSISTED STRIP (UVAS) OF PHOTORESIST TO REALIZE ESG AND 3D INTEGRATION TARGETS

(71) Applicant: VEECO INSTRUMENTS INC., Plainview, NY (US)

(72) Inventors: John Taddei, Marco Island, FL (US); Phillip Tyler, Horsham, PA (US); Matthew Villa, Philadelphia, PA (US); James Kuter, Allentown, PA (US); Robert Kurucz, Oley, PA (US); Kevin Donnelly, Horsham, PA (US); Kevin Kauermann, Southampton, PA (US); Edward Budriss, Hopewell, NJ (US); Simon Bird, Hatboro, PA (US)

(73) Assignee: VEECO INSTRUMENTS INC., Plainview, NY (US)

(21) Appl. No.: 19/183,129

(22) Filed: Apr. 18, 2025

Related U.S. Application Data
(60) Provisional application No. 63/636,378, filed on Apr. 19, 2024.
(60) Provisional application No. 63/672,799, filed on Jul. 18, 2024.

(51) Int. Cl. G03F 7/42; G03F 7/00

(52) U.S. Cl. CPC G03F 7/42; G03F 7/7085

(57) ABSTRACT

A UV-assisted system for stripping a photoresist from a semiconductor substrate that comprises an ultraviolet (UV) exposure station (“UV station”) having a UV radiation source and a UV controller. The UV station is adapted to receive the substrate and to apply UV radiation over an entire surface of the substrate, wherein the UV radiation changes material properties of the photoresist and loosening bonding of the photoresist to the substrate. The system further incudes at least one additional station adapted to receive the substrate after exposure to UV in the UV station and to remove the loosened photoresist from the substrate. The UV controller is configured to modify the dose set point by taking into account an area of the wafer, and an angle of dispersion of the UV radiation from the UV radiation source.

### CROSS REFERENCE TO RELATED APPLICATIONS

The present application claims priority to and the benefit of U.S. patent application Ser. No. 63/636,378, filed Apr. 19, 2024, and U.S. patent application Ser. No. 63/672,799, filed Jul. 18, 2024, each of which is hereby expressly incorporated by reference in its entirety.

### FIELD OF THE DISCLOSURE

The present disclosure relates to semiconductor processing and more particularly, relates to a system and method that incorporates a high intensity UV light source into a wet process toolset that uses solvents or other chemistry to perform a sequential material removal process.

### BACKGROUND OF THE DISCLOSURE

Wet processing has long been a preferred method for thin film photoresist stripping due its effectiveness and low cost of ownership. Wet benches (immersion only), batch spray and single wafer toolsets have proven capable of performing some level of wet resist strip processing. Traditionally, solvents have been employed to perform the task of removing positive and negative tone photoresist through the mechanism of dissolving the resist into the solvents. Example solvents include acetone, NMP (N-methyl pyrrolidinone), DMSO (dimethyl sulfoxide) and proprietary formulations based on these chemistries. The conventional strip inspection process uses mid-level magnification such as via a (50-250×) microscope or, for more demanding applications, a scanning electron microscope (SEM), to verify the absence of large unstripped resist.

Newer process flows, for example for 2.5 and 3D architectures, demand photoresist strip process results that are far in excess of the capability of traditional processes. One example is the stripping of bulk photoresist (PR) of 100 microns (um) thickness or greater for silicon-less interposer process flows. Traditional higher end toolsets have demonstrated the ability to strip the thick resist with recently-developed proprietary solvent mixtures. However, the conventional heated 25L bath life can be extremely short at 5 wafers (as an example). This leads to an unacceptably high usage of the expensive solvent and long process times which negatively impact throughput through the wet process toolset. Accordingly, cost of ownership is excessive due to the capital cost of additional tools, the variable cost of purchasing proprietary solvents and the treatment of excessive hazardous waste. Furthermore, the lengthy process requires significant power to heat and maintain operating temperatures of the large solvent bath. Each change of a bath (every 5 wafers for example) requires cooling water to cool off the bath prior to draining the chemistry followed by the addition of significant energy to raise the temperature of incoming fresh chemistry to refill the bath and obtain the required operating temperature.

Another new process for which traditional strip processes suffer from challenges is stripping positive PR post on a post die singulation, utilizing either mechanical or plasma dicing processes, for a hybrid bonding flow. In this process, a medium to thick PR film (for example 10-50 um) is applied across a wafer. For mechanical dicing a saw blade cuts through the PR protective mask all the way through the wafer. Plasma dice openings in the PR mask are created to permit a plasma etch that removes the silicon substrate between the dice (Bosch process). Subsequently, a heated chemistry (DMSO, TMAH blend for instance) is used to strip the photoresist mask and the sidewall polymers created by the dicing process. The removal of the PR mask exposes the Cu and dielectric surfaces which form contact areas for the hybrid bonding. Hybrid bonding takes place when two surfaces are contacted and then undergo a thermocompression step to become permanently bonded together. Any residues remaining on these surfaces after PR stripping will prevent successful hybrid bonding by inhibiting surface contact. This phenomena is made worse by the unbonded area being 30-100× the dimension of the debris inhibiting contact. Accordingly, the surface must be free of macro and micro contamination. Microscope or SEM inspection alone is insufficient to determine if surfaces will have high yields for hybrid bonding. The industry has added additional measurement methods, such as use of goniometers to determine the contact angle of a droplet on a surface. Typically, in semiconductor processing a clean surface is hydrophilic and a droplet would have a contact angle of 10 degrees. Post strip, a surface that appears clean by microscope or SEM inspection but has a contact angle of 60 is deemed insufficiently clean for hybrid bonding and would not be expected to obtain maximum yield. The cause of the higher contact angle is often a micro-layer of debris that was not removed by the stripping process. Extending the wet process time (2-3× for example) is in many cases a solution for eliminating the micro-layer but for bonding this is not an acceptable solution. The solvent utilized for the PR strip has an etch rate on the exposed CU surfaces of, for example 1.5 nm\min. In this case, a process with ten minutes of solvent exposure results in a 15 nm loss of Cu due to the collateral etching during a resist strip process. While 15 nm is at the high end of acceptable material loss, having 3× the solvent exposure time would result in a 45 nm Cu loss which would be unacceptable due to yield loss.

In addition, wet process has traditionally been employed as an economical and effective means to remove residues, organic films and defects from wafers. But as the industry has followed Moore's Law and has transitioned beyond it, permissible defectivity sizes and quantities have reduced in tandem with decreased feature sizes. Accordingly, process sequences and results that previously met industry requirements no longer meet the new tighter requirements. Examples of the sources for the residuals include: organic films—spin on resist (positive and negative), fluxes, adhesives, and temporary bonding materials (such as adhesives, mechanical release and laser release films). Excessive residues can result from the thermal budget (high temperatures), chemical exposure, wet then dry sequencing or plasma exposure. In order to meet the demands of future products methods to reduce defectivity on the substrate surface need to be developed. Applicable to all semiconductor processing, ESG agendas are also demanding use of fewer resources (power, chemistry . . . ), creation of less hazardous waste and reduction of VOC emissions. This is another impetus for reduction of residues and defects.

### SUMMARY OF THE DISCLOSURE

In a first aspect, the present disclosure provides a UV-assisted system for stripping a photoresist from a semiconductor substrate comprises an ultraviolet (UV) exposure station (“UV station”) having a UV radiation source and a UV controller. The UV station is adapted to receive the substrate and to apply UV radiation over an entire surface of the substrate, wherein the UV radiation changes material properties of the positive photoresist, increasing solubility and in a wider range chemistries and loosening bonding of the photoresist to the substrate. The system further includes at least one additional station adapted to receive the substrate after exposure to UV in the UV station and to remove the loosened photoresist from the substrate.

In another aspect, the present disclosure provides a UV-assisted method for stripping a photoresist from a semiconductor substrate. The method comprises exposing an entire surface of the substrate to a dose of UV radiation, the UV radiation changing material properties of the photoresist and loosening bonding of the photoresist to the substrate and processing the substrate using wet chemistry to remove the loosened photoresist from the substrate.

These and other aspects, features, and advantages can be appreciated from the following description of certain embodiments and the accompanying drawing figures and claims.

### BRIEF DESCRIPTION OF THE DRAWINGS

FIGS. 1A-1C are schematic diagrams of a conventional photoresist stripping method.

FIGS. 2A-2D are schematic diagrams of a UV-assisted photoresist stripping method according to an embodiment of the present disclosed.

FIGS. 3A and 3B are schematic diagrams of an implementation of a UV-assisted photoresist stripping process according to the present disclosure used to stripping a thick layer of photoresist from copper vias or features.

FIG. 4A is a schematic diagram of hybrid bonding of two wafers by a bulge-out process.

FIG. 4B is a schematic illustration of several common defects that can occur during hybrid bonding when residues and defects are not removed prior to bonding.

FIG. 5 is a flow chart of an embodiment of a method of a UV-assisted photoresist stripping according to the present disclosure.

FIG. 6 is a schematic illustration of a UV station including a light source that is used to irradiate photoresist and other materials in the UV-assisted stripping methods of the present disclosure.

FIG. 7A is a graph showing irradiance of an exemplary UV light source versus the distance of the UV light source from a wafer being irradiated.

FIG. 7B is a graph showing relative power per unit length of UV radiation exposure on a wafer versus longitudinal displacement for an exemplary UV light source.

FIG. 8 is a graph (with listed parameters) of wafer temperature response versus UV exposure time at different UV intensities for an exemplary DSXUV-12 UV light source.

FIG. 9 is a graph (with listed parameters) of wafer temperature response versus UV exposure time for different numbers of scan passes across an exemplary UV light source.

FIG. 10 is a group of photographs that compare contact angles on a wafer surface for three different process states: left (unprocessed); middle (processed using wet chemistry without UV exposure); right (processed using wet chemistry with UV exposure.

FIG. 11 is a table with parameters of wet photoresist stripping a UV-assisted photoresist stripping for an exemplary sample set.

FIGS. 12A-12D are schematic illustrations of a process of ion beam etch burr creation and removal using carbon dioxide which can be used in association with the UV station and UV-assisted photoresist stripping according to the present disclosure.

FIG. 13 is a schematic illustration of an integrated atmospheric plasma station that can be used with a UV station according to the present disclosure.

FIG. 14A is a top-angled perspective view of a stand-alone UV exposure station 1400 with a cover in place.

FIG. 14B is an exploded view of the UV station shown in FIG. 14A.

FIG. 14C is a plan view of the back of the removable cover which holds the door through which wafer modules are transferred into and out of the UV station.

FIG. 14D is the enlarged view of section A shown in FIG. 14C.

FIG. 15 is a side view of a vertical cross-sectional of the UV station.

FIG. 16 is a perspective view of the UV head and linear drive within the UV station.

FIG. 17 is a top plan view showing the UV head linear drive and a wafer.

FIG. 18 is an enlarged side view of a UV head flex joint.

FIG. 19 is a side view of assembly for mitigating expansion of the UV light Source slide rail.

FIG. 20 is a schematic plan view showing a cooling plate on which a wafer 2 is placed via a chuck that holds the wafer.

FIG. 21 is a side cross-sectional view of an active water cooling assembly which includes an air knife positioned on the UV head.

FIG. 22 is an enlarged view of a section of the air knife shown in FIG. 21.

FIG. 23 is a perspective view of an embodiment of a UV radiation unit.

FIG. 24 is a schematic view of a UV head applying a concentrated dose of radiation onto to a focused area of a wafer.

FIG. 25 is a perspective view of a UV light source showing an implementation of light shutters that are used to block light from potentially bleeding out from around the UV light source.

FIG. 26 is a perspective view of the UV light source that illustrates the substrate temperature monitoring capability via a real time temperature transmitter positioned at the center line of the wafer.

FIG. 27 is a schematic illustration of a mechanism for UV dose control.

FIG. 28 is a schematic diagram illustrating aspects of UV dose control.

### DESCRIPTION OF CERTAIN EMBODIMENTS OF THE DISCLOSURE

The present disclosure describes an apparatus and method for utilizing a wet chemical process to perform an organic film or material removal process, such as, for example, a positive photoresist strip process. More specifically, the method is a combination of a dry process and a wet process which integrates a high intensity ultraviolet (UV) light source within the wet process tool set. The ultraviolet assisted strip (UVAS) process derives significant benefits beyond a traditional wet-only process in terms of lower defectivity, higher yield, lower cost of ownership (COO) and accomplishes a number of Environmental, Social and Governance (ESG) goals.

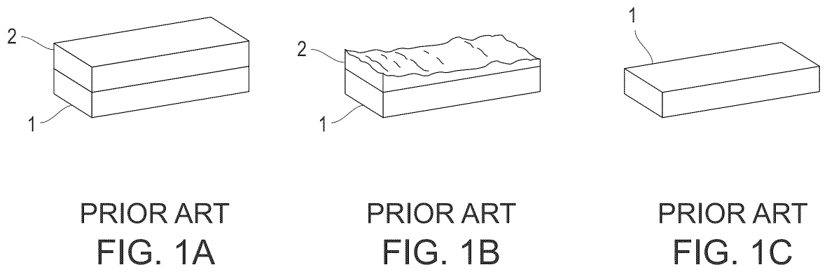

FIGS. 1A-1C are schematic diagrams of a conventional photoresist stripping process. As shown in FIG. 1A, a wafer 1 with a film of photoresist (PR) 2 undergoes a wet process (shown in the FIG. 1B), typically with heated solvent that dissolves the PR (layer) 2, resulting in a clean and dry wafer 1 shown in FIG. 1C by historical standards.

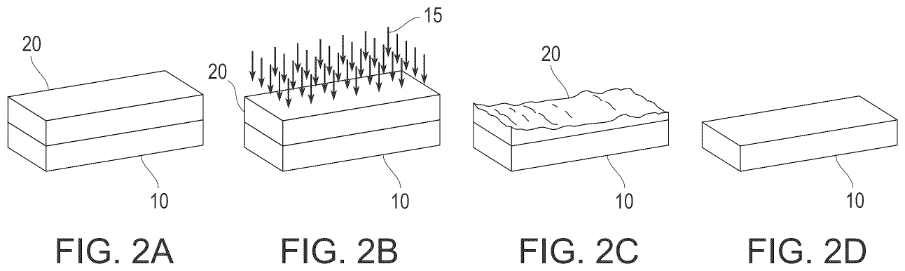

FIGS. 2A-2D illustrate the UVAS (UV assisted strip) process according to one embodiment of the present disclosure. In a first stage shown in FIG. 2A, a wafer 10 with a PR layer 20 is shown. In a second stage shown in FIG. 2B, UV (light) radiation, generally indicated at 15, is applied to the photoresist layer 20 to change the light sensitive PR compounds (forming layer 20), loosening the compounds from adhesion to underlying substrate layers (wafer 10). It is noted that the UV light is not patterned but rather covers the entire surface of the PR layer 20. After UV exposure, the PR layer 20 is easier to strip and therefore requires less aggressive wet processes or non-solvent chemistries to remove, as shown in the stage of FIG. 2C. Finally, in a subsequent stage shown in FIG. 2D, the surface of the wafer 10 post PR stripping is more defect free.

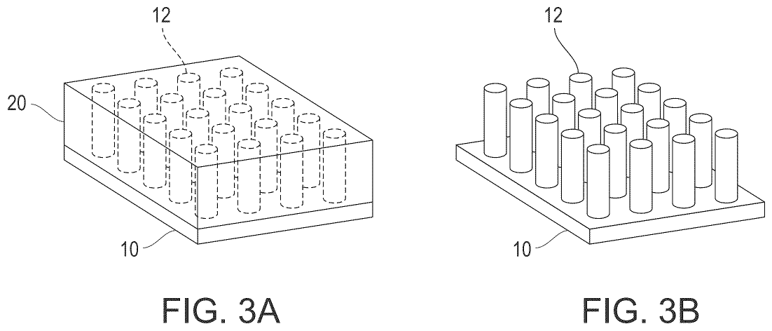

One of the notable applications of the UV-assisted PR stripping method of the present disclosure is the removal of relatively PR layers from patterned metal (e.g. Cu) vias and other features used for 2.5D and 3.D fabrication. This process is shown schematically in FIGS. 3A and 3B. In certain implementations of this application, the requirement is to strip about 150 μm of positive photoresist mask layer used in the fabrication of 140-μm high-aspect ratio Cu vias on a 300 mm silicon wafer. More particularly, FIG. 3A shows a wafer 10 that includes Cu vias 12 or other similar features that is coated with PR layer 20. As discussed herein, according to the present teachings, the PR coated wafer of FIG. 3A is subjected to a complete UV exposure of all of the PR 20. In other words, all of the PR layer 20 is exposed to UV light. Subsequently and post UV exposure, the PR coated wafer is then subjected to a wet chemical strip process with a dilute base developer (or equivalent process) for stripping the PR layer 20. The wet chemical strip process can include an immersion step and a high pressure chemical spray. FIG. 3B shows post strip vias 12 with seed layer exposed.

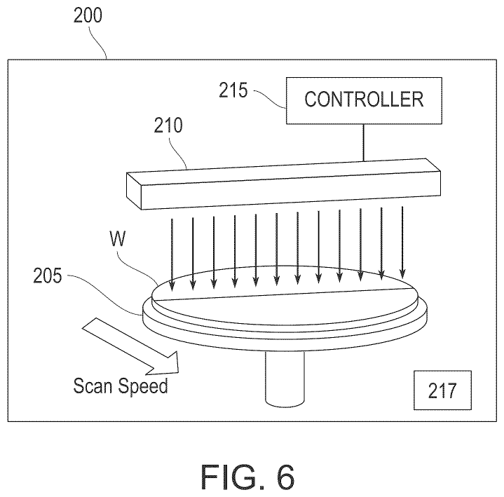

In certain embodiments an integrated system with several station units, each having specific toolsets, is used in the PR stripping process. The stations include at least a UV station, and a wet process station, and can include a number of additional stations, including spinning, drying, rinsing, an ion beam etch, plasma etch, etc. In an exemplary PR stripping process, the wafer carrying the vias and PR layer is initially withdrawn from an input station (such as a cassette or FOUP) through the use an integrated robot that can transfer the substrate between stations and within the toolsets. A non-contact alignment step is then performed on the wafer to determine the deviation from a target position for the wafer. Any deviation is adjusted into the placement location so that the wafer ends up in the proper position in the UV exposure station (“UV station”). As shown in FIG. 6, the UV station 200 includes a chuck 205 for holding the wafer (W) in a defined location, a UV (light) source 210 capable of radiation in the UV band (e.g., 365 nm, 385 nm, 395nm and 405 nm, but other wavelengths are possible), and a controller adapted to activate/deactivate the UV source according to electronic and/or programmed commands. In operation, the UV station chuck 205 can then be moved so that the wafer is positioned progressively under the UV source 210 so that the entire surface of the wafer is exposed to the UV radiation (source 210). Alternatively, in certain embodiments the UV light source 210 can be moved rather than or in addition to the chuck 205. In addition, in certain embodiments, the wafer, rather than being placed on a chuck 205, remains on the paddle of the robot within the toolset. The robot arm can support the programmed motion of speed and time under the UV source 210. In this embodiment, the Z motor of the main robot maintains the distance between the substrate and the UV source 210. In all embodiments, the entire surface of the wafer is exposed to the UV light source by moving the wafer and or moving the UV light source or by a combination thereof.

In some embodiments, the UV source 210 is a lightbar approximately 25 mm wide and 330 mm long that includes a 2,000-Watt intensity array of LED sources arranged so that the exposed area is one source deep and extends beyond the edges of the wafer edge (300 mm for this example). The dimensions allow the entire wafer is covered by the UV source in a single pass. UV intensity at the substrate surface is a function of the distance between the light source and the substrate. Accordingly, the controller 215 (shown in FIG. 6) is configured to adjust the height of the UV source 210 via a motor to attain a targeted vale of a Z parameter, defined as the distance between the substrate and the UV source 210 for achieving a desired intensity. Working values of Z are typically 1-50 mm. The UV source 210 is designed to illuminate beyond the edge of the substrate (wafer) at a minimum working distance. Movement of the chuck 205 at a constant speed with respect to the UV source 210 provides uniform exposure to the entire wafer. The exposure dose is controlled by total time under the UV light source 210. This design accounts for an increase in illuminated area as the working distance (length substrate to UV source) is increased due to the spreading of radiation. As Z increases, the dosage of UV per unit area on the surface of the substrate decreases; however, the dosage is uniform across the wafer. The areas beyond the wafer edge would have minimal to no irradiation at small working distances but increased exposure at greater working distances. As these areas beyond the wafer edge do not affect the process results it is not a concern. The UV station 200 is designed to contain the UV emitted from the source so as to not expose areas unnecessarily to UV radiation through the use of UV shields.

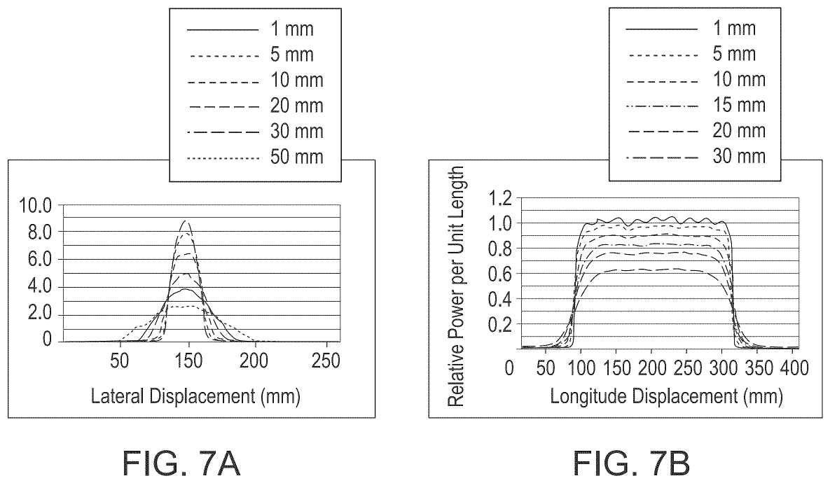

FIG. 7A shows the effects of distance on irradiance at the contact zone for the width of the area illuminated (i.e., UV light irradiance versus working distance). As the substrate is moved further away from the source the radiation contact zone widens. At minimum distance the UV contact width is near the 25 mm dimension of the UV source. At the 50 mm distance the radiation contact width increases to nearly 100 mm. FIG. 7B shows the effects of distance on the length of illuminated area of contact (i.e., UV light irradiance versus lateral position and working distance for a 200 mm system). In this case, the UV contact zone expands as for the width case; however, for much of the area the UV simply contacts the wafer in a different location. As shown in the irradiance graphs, the area that has the greatest impact in reduced dose is the outer 20 mm. Accordingly, the length of the light source is designed for uniformity of UV dose over the working distance range for the size of the substrate. In this example a 200 mm wafer would have a uniform but decreasing dosage as the working distance is enlarged. The areas that are up to 20 mm beyond the substrate are illuminated but suffer a significant change in UV dose. Since the wafer does not occupy these areas this does not affect the process.

There is an optimal level of exposure dosage and wavelength for each PR and thickness. The exposure to UV radiation at the active wavelength changes the physical properties of photosensitive compounds within the PR. Films unexposed to UV radiation can be removed by being dissolved at a moderate rate in heated solvent (e.g., 80C DMSO based solvent) but either cannot be developed (dissolved) by a developing solution (2.5% TMAH for instance) or can only be dissolved at a small fraction of the rate (for example 0.2 nm/sec) as compared to a heated solvent. However, once exposed to UV radiation the development rate is boosted by orders of magnitude (to 70 nm/sec for instance) and the develop rate typically offers >100:1 selectivity (in this example 350:1) for developing chemistry for optimally exposed PR verses unexposed PR. Solvents that contain a developing agent will also see a boost in PR strip rate when UV exposure occurs.

The high intensity UV source is designed and positioned to provide minimum exposure time and therefore maximum throughput through the UV station when it is used at full power. The high intensity UV source imparts significant heat onto the wafer and causes its temperature to rise. In many cutting-edge process flows there is a thermal budget (or maximum temperature the substrate can reach), set to 70° C. for instance. Temperatures above this point can result in negative consequences such as yield loss through material migration or can produce temporary films that are far more difficult to remove. A number of features can be incorporated into the design to mitigate temperature rise and maintain the thermal budget. The chuck 205 that holds the wafer can be constructed of a conductive material of sufficient mass and contact area to maximize heat transfer away from the wafer surface. The UV station can be constructed with a flow of cool N₂ or CDA to reduce the temperature within the station. In another variation the chuck can be equipped with cooling fluid to minimize temperature. The chuck movement can support a recipe that controls scan speed and total time of exposure.

In certain embodiments, the UV station includes a UV dose measurement device, generally shown at 217 in FIG. 6. The UV dose measurement device can be located on the wafer chuck or another area that receives identical dosage as the wafer itself. The device measures and the controller records and estimates the total UV exposure delivered by the UV station. The total dosage is checked against the recipe dosage and alarm if actual UV dosage is not within tolerances.

It has been documented that the increase in temperature on the exposed wafer is partially localized to the time and location where the UV radiation contacts the wafer surface. By speeding up the movement of the wafer under the UV radiation, the local areas heat up to a fraction of the temperature rise compared to a full dose in a single slow scan. Thus, moving the wafer quickly under the UV source reduces the temperature rise. Therefore, multiple passes are used to obtain the desired target UV dose for minimizing the temperature rise. This technique works because as soon as the portion of the wafer is passed through the UV radiation contact zone, the surface begins to cool through chuck contact and the cooling gases. Accordingly, the temperature rise can be minimized greatly, even at full power supplied to the UV LEDS. In testing, a single pass resulted in a max temperature of 140° C., while dividing the same exposure time into twenty scans resulted in a maximum temperature of 63° C. In another variation the power to the UV LED array can be regulated by recipe. Less power translates to less heat but since the UV is also diminished it takes a longer time to reach a prescribed dose as compared to a full power process. Accordingly, the invention is equipped with power setpoint in the recipe and a means to limit UV output, but it is a parameter of last choice to maintain the thermal budget.

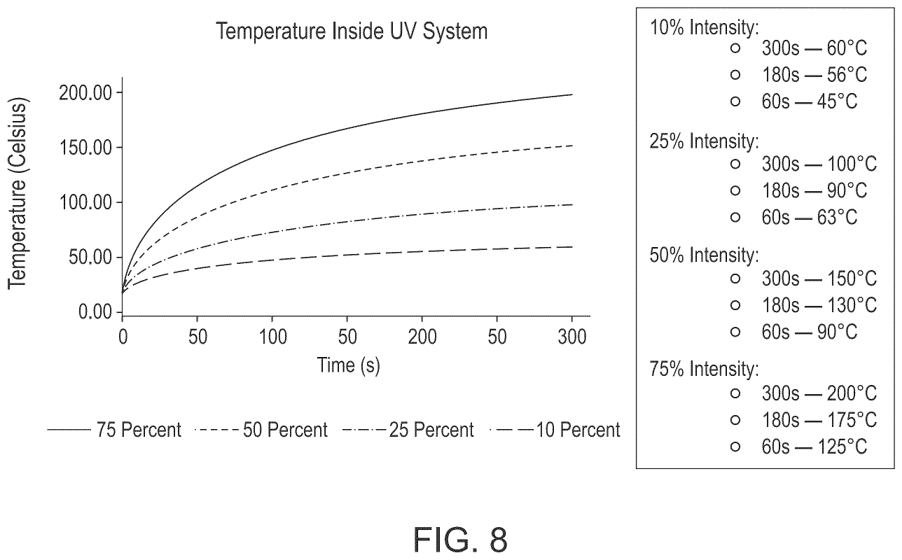

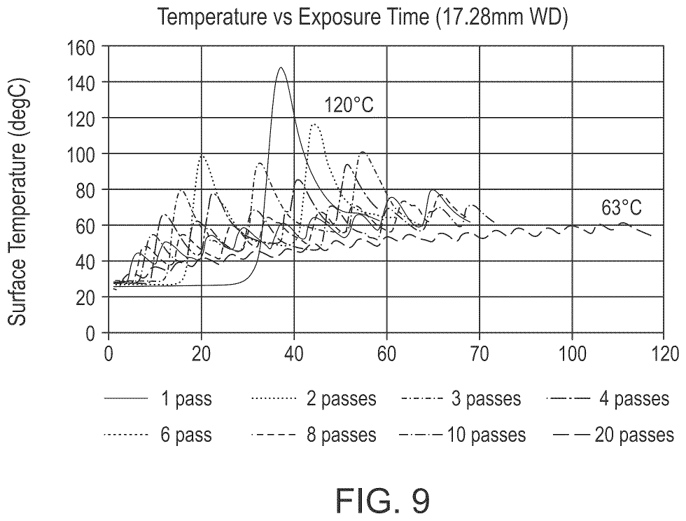

FIG. 8 is a graph showing surface temperature varies proportionally with UV parameters of power and time. In this figure, the UV exposure is being explored as a method for a more efficient and improved positive tone removal process. In this example, the DSXUV-12 is the current UV tool being test: wavelength: 365 nm and illuminance: 600 mW/cm². The temperature effects of the UV system were explored. The temperature was measured at different UV intensities w/TC (intensity measured in percentages). Accordingly, the maximum temperature on the wafer surface can be controlled by these parameters. FIG. 9 shows the maximum temperature reached on the wafer surface for identical UV dosages and conditions with the exception of the number scans beneath the UV source. The temperature decreases from over 140° C. for a single scan to a maximum of 63° C. for 20 scans within the same overall time as the single scan. The maximum temperature was reduced by approximately 48% changing 2 UV passes to 20 passes (same overally dose, faster scan).

Once the wafer has been exposed to the UV light, it is transferred by robot from the UV station to an immersion station. At the immersion station, the wafer is submerged for sufficient time to swell and significantly dissolve the PR bulk layer. For wafers not exposed to proper UV dosage the immersion would require heated solvent. For wafers that are properly dosed with UV radiation, an ambient, dilute developing chemistry (2.5% TMAH for instance) is sufficient to strip the PR. This method has the benefit of using less energy (ambient vs heated), strips the resist at a faster rate (higher throughput, lower capital costs), and improved ESG metrics (eliminates the need for solvent by using a dilute base as chemistry, eliminates need for IPA rinse, lowers chemical usage through extending bath life and reducing hazardous waste quantities produced) and lowers VOC emissions). Once the optimal immersion time is reached the wafer is transported wet to a stripping chemistry spray station (FIG. 1B). At the spray station, the wafer is sprayed with an aggressive (high velocity or high-pressure spray). Chemical removal from the wafer is assisted by a physical removal via the aggressive spray. The wafer can again be transferred wet to a separate Spin Rinse Dry (SRD) chamber for removing all chemistry from the wafer with a rinsing agent (for example DI water). After the wafer surface is free of chemistry the wafer can be spun dry. At this point the wafer is picked up by the handler and then placed to its output destination (for example a FOUP).

To those of ordinary skill in the art, it will be understood the embodiment described above is in no way restrictive and many variations are prudent and marketable.

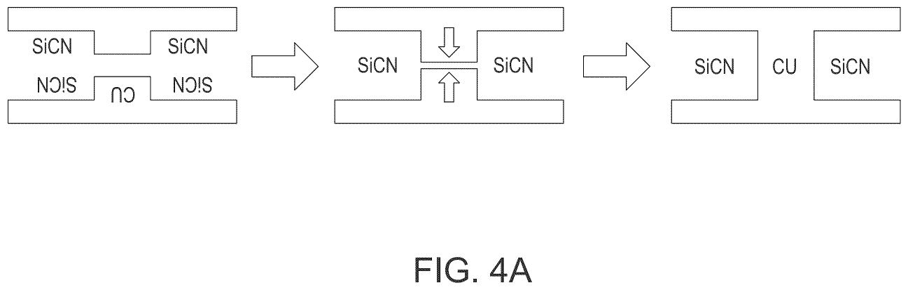

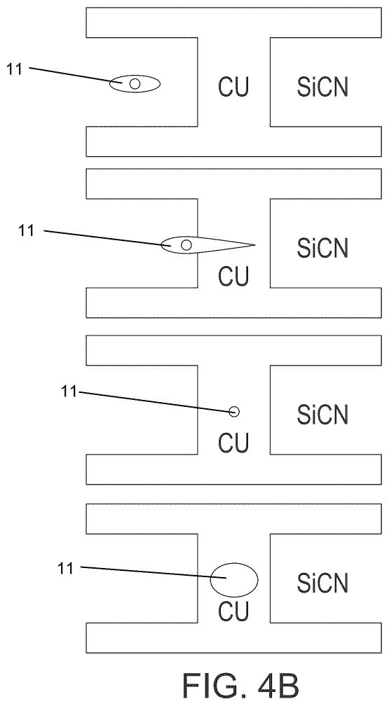

As noted, the embodiment described above can be used for PR stripping from wafers with Cu vias. Substrates with Cu vias that have undergone a post dicing strip can then be bonded together. A schematic illustration of a bonding process is shown in FIG. 4A. The two active sides of the wafers (via or bonding pad bearing) face each other (left image) and undergo a thermocompression step. The dielectric layers are slightly elevated in comparison to the Cu surfaces. The dielectric layers bond initially and then the Cu features bulge out due to thermal expansion to come into contact with each other (middle image). Once the Cu surfaces contact, they become permanently bonded (right image). It can be seen that if the Cu surfaces are too far apart they would not contact one another and not bond. One cause for such excessive Cu recess is overexposure to solvent during the PR mask strip that etches too much Cu during the PR strip, which is avoided using the UVAS method of the present disclosure.

The UVAS process thus provides benefits for the hybrid bonding sequence, particularly during the stripping of the PR mask used for protection of surfaces during the die singulation (or dicing step). As noted, the use of the integrated UV-assisted shortens chemical exposure time compared to traditional solvent based stripping processes. The reduced exposure time results in correspondingly reduced collateral etching of Cu that degrades hybrid bonding yield. These Cu areas that will bond are exposed by the PR mask strip. Eliminating collateral Cu etching is important as Cu etches faster than the dielectric areas that are at the same height under the PR mask. The etching of the Cu areas would place them at a lower elevation and therefore during bonding the dielectric areas would contact and bond but potentially the Cu areas would be recessed and too far apart to properly bond. The surfaces to be bonded must be co-planar (at nearly the same height as the dielectric areas to be bonded) so that when contact is made both CU and the dielectric can properly bond. The UVAS process also delivers a cleaner surface of the residual CU areas to bond through better removal of macro and micro contamination on the areas that will bond. Furthermore, UV exposure enables the elimination of the use of solvent through the activation of the photo sensitive compounds in the PR to permit non-solvents to remove the PR strip for these steps. Elimination of the solvent enables a range of ESG goals to be accomplished including less chemical usage, less hazardous waste creation, lower power usage and higher throughputs.

FIG. 4B schematically illustrates cases of effects of a surface that is not pristine. In particular, defectivity induced voids are shown in the figure (e.g., as represented by oblong, oval or circular shaped voids identified by reference character 11). Residual contamination from the post dice PR strip left on the wafer surface impedes hybrid bonding. Depending on the composition, size and location of the debris, the ill effects range from underperforming features all the way to complete yield loss from a non-operational device. Debris can cause voids (non-contact) between surfaces or surfaces forming around that debris that reduce operation effectiveness or even render devices useless. More particularly, the top image illustrates a post strip contamination that would slightly impact yield. The second image from the top illustrates contamination post strip that would impact yield. The third image from the top illustrates a post strip contamination that would likely impact yield. The bottom image illustrates contamination post strip that would impact yield.

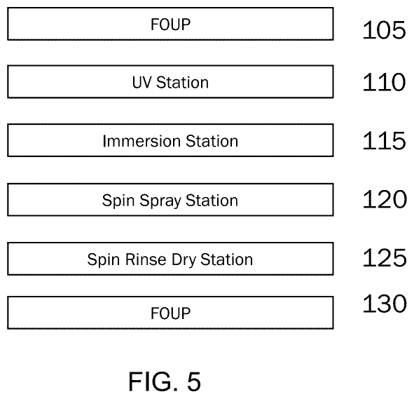

FIG. 5 is a flow chart of an embodiment of a UVAS method according to the present disclosure. After wafers have been initially loaded onto the tool using a FOUP, in a first step 105, the robot withdraws wafers from the FOUP and takes them one at a time to the UV station. In the UV station the wafer receives the prescribed dose of UV in step 110. In step 115, the exposed wafers are then transferred to an immersion station and immersed in chemistry for a prescribed time. After soaking in the immersion station, the wafers are moved wet to the solvent spray station in step 120 where they receive a spin process with wet chemistry dispensed upon them to remove any residual PR or residues. After the chemical spray station, the wafers are again moved wet into the spin rinse dry station in step 125. Here DI water or other rinsing fluid is used to displace any chemistry from wafer along with any residual debris, prior to a spin-dry cycle. The clean, PR free wafer is then transferred to an output FOUP in step 130.

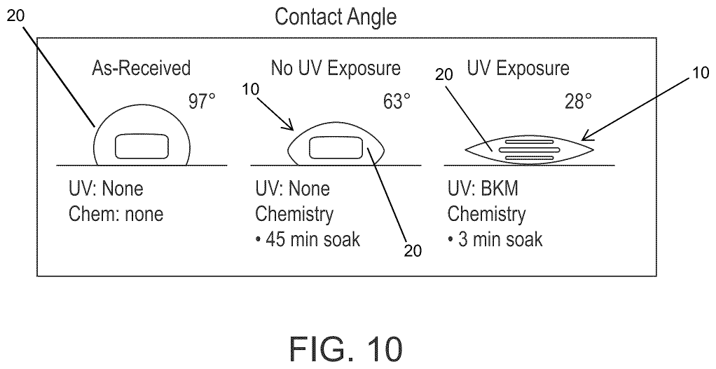

The improved surface stripping provided by UVAS is demonstrated by the contact angle (CA) of droplets placed on the stripped surface during measurement with a goniometer. FIG. 10 shows contact angles for three conditions in a limited sample set. The incoming wafer 10 (left image) with the PR film 20 on top has a 97-degree CA. The wafer 10 processed with a traditional solvent-only PR strip process without UV-assisted (middle image) showed a 63-degree CA. This shows the bulk PR 20 was properly stripped but that there remain surface contaminants which prevent a low CA. The third image (right image) shows a UV-assisted and identical solvent PR strip sample having a CA of 28 degrees. Although by microscope or SEM inspection samples 2 and 3 can appear identical, the CA clearly shows the third sample as having a more pristine surface. In one embodiment, the UV exposure was at an intensity: 95% (1200 mW/cm²); speed: 1 in/sec and WD: 0.75 in. The decrease in the contact angle indicated improved wettability and higher surface energy. This correlates with a cleaner surface for silicon. For reference, a base silicon wafer as a contact angle of approximately 15 degrees.

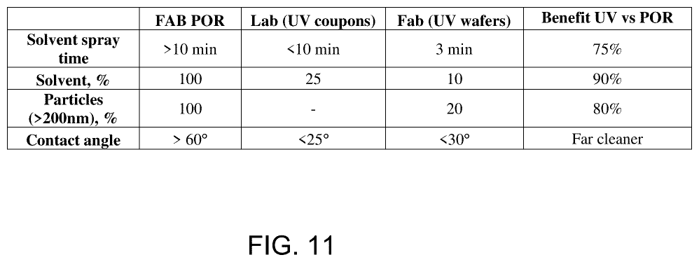

The table shown in FIG. 11 provides some of the benefits of including UV as part of the wet PR strip process for one sample set. Chemical time required to strip the PR is reduced by 75%. This directly translates to reduced collateral material etching due to chemical exposure and increased throughput through the system. The chemical usage is reduced by 90%. This translates to a similar reduction in hazardous waste creation. Particles found by Surfscan (an automated defect inspection system at 200 nm and larger defects) were reduced by 80%. The contact angle was significantly reduced, an indication of a far more pristine surface (far cleaner surface).

The system and method of the present disclosure can be used and configured in other embodiments. For example, in place of a 300 mm silicon wafer, any number of SEMI standard or non-standard wafers can be used. Masks, wafers on tape frame or other functional substrates could undergo the UVAS process. Wafers can be comprised of many materials beyond Si including but not limited to GaAs, InP, AlTiC, Glass, Sapphire and SiC. Wafers can be featureless or contain, but not be limited to, features and films comprised of dielectrics (silicon oxide, silicon nitride, SiCN . . . ), barrier films (Ti, TiW . . . ) to prevent Cu migration and conductive films (CU− seed and electroplated, Al, Co, RU, etc.).

In embodiments involving processes that would otherwise be UV station throughput limited, multiple UV stations can be employed to permit other process stations within the toolset to run at their capacity.

In some embodiments, one or more stations of the system can include a camera to monitor the intensity of visible radiation reflected off the substrate surface during certain processes. An electronic controller can receive and store data from the camera and use the data to compare the intensity to a model of an anticipated change in intensity. For example, the controller can be configured with software that provides a setpoint to be utilized as a method to determine when the spin portion of the wet process has been completed based on the intensity of the reflected light. This can be done on a per-recipe basis.

A controller of the immersion station is configured to utilize the UV exposure dose applied in the UV station to define the wet process performed to strip the PR. Lightly dosed PR films require more aggressive chemical processes than more thoroughly dosed PR films. Optimally dosed wafers will require less aggressive processing to completely strip the PR film. Over exposed wafers will damage the PR film and make the PR more difficult to strip. Accordingly, the dosage applied to the PR film determines immersion time by adjustments to the aggressiveness of the solvent spray (time, pressure and height of spray) by software control to deliver required processing conditions at each exposure level.

It will be appreciated by those of skill in the art, that the single wafer three step (immersion, chemical spray and SRD) process described above can be carried out in other toolsets and configurations. In other embodiments, wet benches, batch spray tools and spin-only single wafer toolsets can replicate the dry-wet sequential process with one or more wet process chambers, although there would likely be some compromises to the process results. Two examples of variations to the first embodiment are a two-wet chamber approach with immersion followed by a single spin chamber that accomplishes chemical spray plus an integrated SRD within a single spin chamber. An additional variation is the omission of the immersion step by single wafer PR strip and SRD, either in a single chamber or two chambers in series.

As discussed, UV exposure integrated within the wet chemical toolset according to the present disclosure increases the ability to remove contamination on the wafer surface. The UV-assisted cleans can be enhanced for residues associated with organic films-spin on resist (positive and negative), fluxes, adhesives, temporary bonding materials (such as adhesives, mechanical release and laser release films). UV exposure immediately prior to or post many wet chemical applications including immersion, low pressure spray, aggressive spray (HVS and HPC), ultrasonic, Megasonic, and brushing offers process advantages such as higher debris removal, decreased defectivity, shorter process times, reduced chemical usage and less hazardous waste creation. It is known to those of skill in the art that debris on a wafer surface becomes more difficult to remove the longer it stays on the surface. The elimination of a queue time is accomplished through the integration of the UV unit onto the wet process tool. Queue time is taken from hours or even days down to seconds between UV exposure and wet processing.

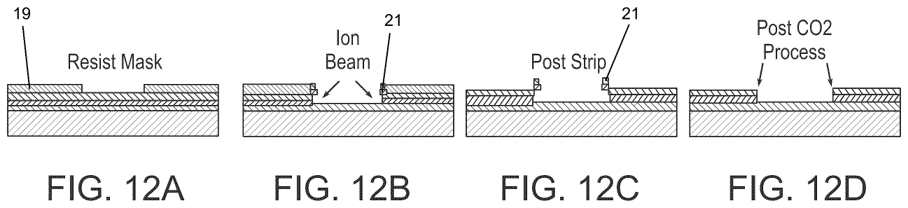

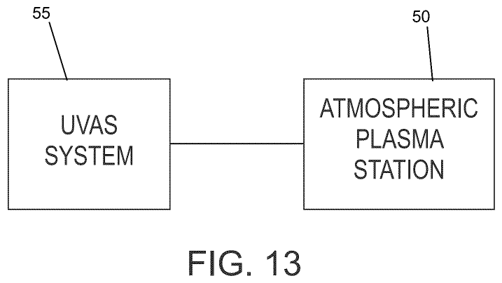

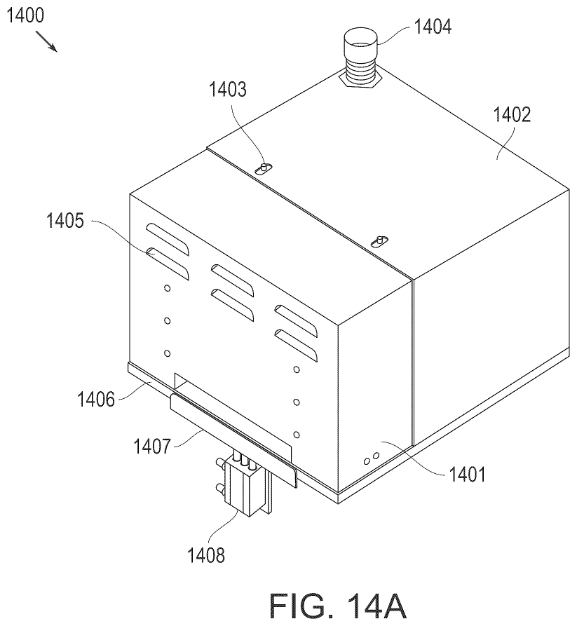

In other embodiments, the UVAS process can be incorporated into a dry etch PR mask removal and deburring process. Ion beam etching removes metal films from openings in the PR mask. These metals will be displaced, and some pushed onto areas at the edge of the mask opening. The PR mask strip process will remove the PR but depending on metal and mask geometries burrs can be left at the edges of the mask openings. While incorporating UV exposure as part of the strip process will yield the benefits previously highlighted, removing any metals at the edge (burrs) requires an additional technology. The incorporation of an integrated CO₂ crystal dispenses to deliver solid, dry CO₂ crystals of specific size, velocity and temperature to physically dislodge and remove burrs is an example of such additional technology. FIGS. 12A-12D provide schematic illustrations of ion beam etch burr creation and CO₂ removal. FIG. 12A shows a PR mask 19 formed for ion beam etch. FIG. 12B shows that the ion beam etch displaces top metal layers in open areas of the mask 19, thereby creating burrs 21. FIG. 12C illustrates that the wet strip process removes the PR mask 19 but the burrs 21 remain. FIG. 12D illustrates a post CO2 process that physically removes the burrs 21.

The UVAS process for PR strip can also be followed by an additional integrated step of atmospheric plasma on to the UVAS platform. After the UV and wet strip process atmospheric plasma supported by O₂ for organic removal, H₂\He for oxidized Cu removal and\or N₂ for drying marks, oxides and other surface residues. In this case, the superior UVAS surface cleanliness levels are even further enhanced for processes such as the pre-hybrid bond clean or pre-UBM etch strip through an addition atmospheric plasma step. FIG. 13 schematically shows a plasma station 50 that can be integrated into the UVAS platform 55 as one skilled will readily appreciate. In one example, the plasma station can have the following attributes and functionality: gases: mixtures of N₂, H₂, He or O₂; power is a max 200 W; adjustable wafer to head gap in mm; and stage speed from 0.5 to 10 mm/s. The target applications can be: temporary bonding material (TBM) clean; pre-UBM etch descum; surface preparation and modification; via residue removal and flux residue removal.

New 3D process flows, such as those for thick (e.g., >100 μm) resist applications and those for post-die singulation PR mask strip on hybrid bonding, are driving tighter process requirements for photoresist stripping. The UVAS process meets these requirements by providing cleaner surfaces (lower contact angle) and less residual Cu loss (minimization of solvent exposure time) to maximize hybrid bonding yield and lowering COO. Benefits to ESG include: longer chemical life, less hazardous waste creation, elimination of solvent in the strip step through UV activation of photo sensitive compounds in the PR, lower VOC emissions by eliminating IPA as a rinsing medium, lower power usage by operating at ambient instead of elevated temperatures and higher throughputs to reduce the number of toolsets required for a given.

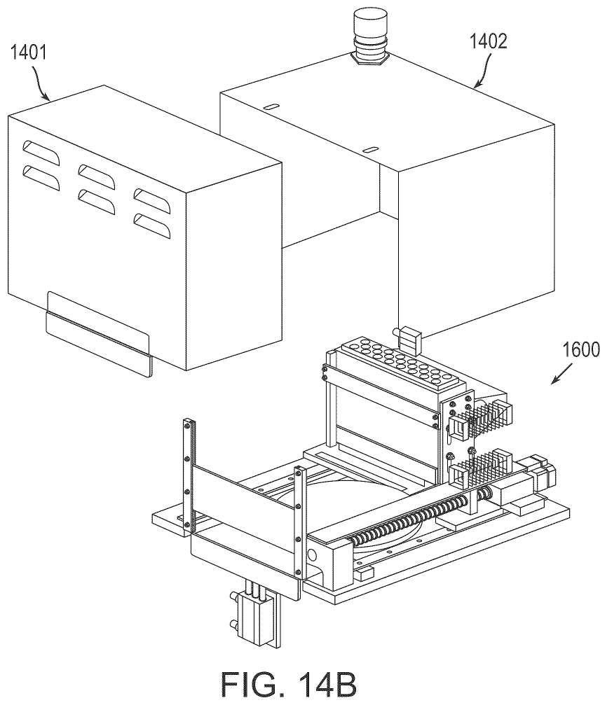

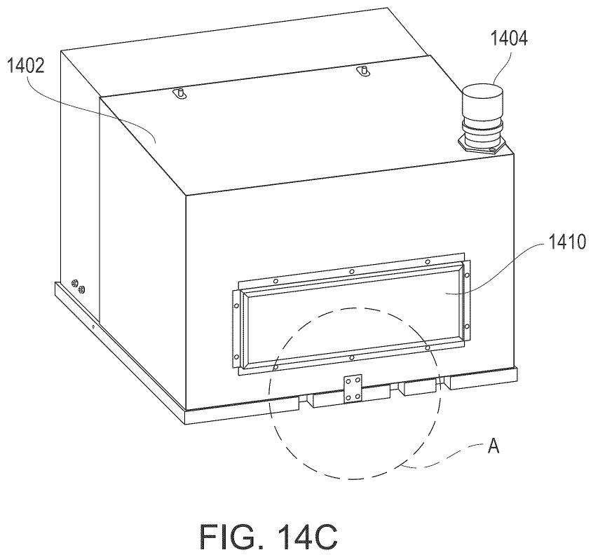

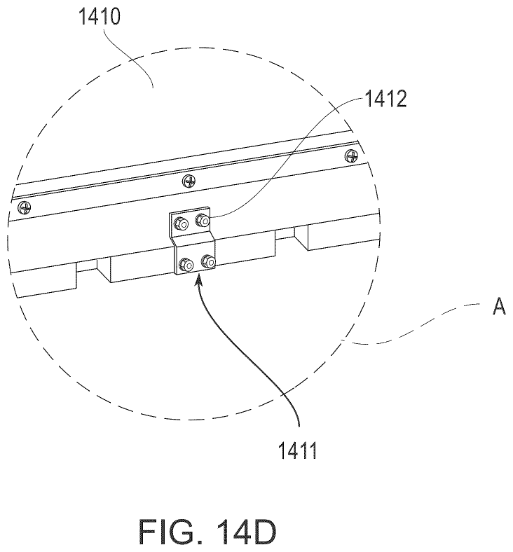

In another embodiment that supports high volume manufacturing, the UV station design incorporates design features that are integrated to support safety, process performance and increase throughput. FIG. 14A is a top-angled perspective view of a stand-alone UV exposure station 1400 with a cover in place. The cover has a two-piece design and comprises a stationary portion 1401 and a removable portion 1402. The removable portion 1402 is held in place by ergonomic fasteners 1403 that promote easy removal. Extending through the removable cover is an exhaust pipe 1404. Air ducts 1405 are incorporated into the stationary cover to permit clean make up air to enter the UV station. The UV station 1400 is mounted on a base plate 1406. The UV station 1400 further includes a door 1407 that permits wafer exchange between an automated robot or handler and the chuck of the UV station. The door 1407 is opened and closed by a door actuator 1408 which is mounted to the base plate 1406. The door 1407 is designed to block any direct path between the UV light source and the door exit when the door is closed. This design prevents unacceptable UV exposure of non-UV station equipment and personnel. Door open and door closed sensors (not shown in FIG. 14A) provide feedback as to the state of the door position. The open and closed door sensors are used to interlock UV light operation to prevent UV illumination when the door is open. It will be appreciated that many different types of door open and closed sensors exist and are suitable. For example, an optical sensor at or proximate the door 1407 can be used to detect the open or closed state of the door or a mechanical sensor, such as a switch can be used such that when the door is closed, the switch is in one state, such as closed, and when the door is open, the door is in another state (e.g., open). FIG. 14B is an exploded view of the UV station shown in FIG. 14A. FIG. 14B shows the stationary cover 1401 separated from the removable cover 1402 as well as the UV head 1600 which is positioned within the UV station. FIG. 14C is a plan view of the back of the removable cover 1402 which holds the door 1410 through which wafer modules are transferred into and out of the UV station. Section A circled in FIG. 14C includes locking features for the door. FIG. 14D is the enlarged view of section A of FIG. 14C showing a door safety interlock 1411 for door 1410 which includes a cover-present sensor 1412 as an additional safety device. The UV light source is prevented from emitting UV if either the door-closed sensor for the wafer exchange door 1403 or the safety cover present sensor 1412 is not activated. It will be appreciated that circuitry is developed for operation in which the aforementioned sensors (door closed and cover (lid) present) act as switches and provide inputs to a processor that controls operation of the UV light source and prevents inadvertent UV light exposure and operation.

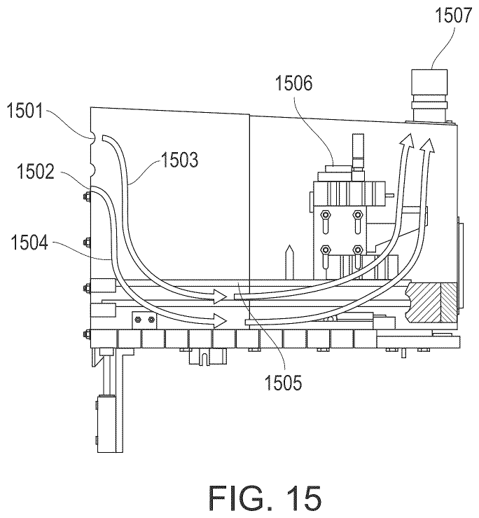

The high intensity UV source typically creates a great deal of undesired heat within the UV station. FIG. 15 is a side view of a vertical cross-sectional of the UV station. Air ducts 1501 and tolerance openings in the door 1502 provide clean make-up air flows. The make-up air enters the UV station at ambient temperature, which is cooler than the air within the station that is heated from the UV light source. Accordingly, the air flow path 1503 from the air ducts 1501 is downward and across the wafer on the chuck. As heat from the UV light raises the air temperature the air rises and is withdrawn through the exhaust duct. Air flow through that enters through the excess tolerances of door opening 1502 enters at wafer level at the bottom of the chamber and then flows across the wafer location 1505. Air flow 1504 then flows across the UV light source 1506 and rises both through expansion when heated and through the pull of exhaust to join the air from the ducts at the exhaust point 1507. The cooling air moderates temperature increases while additional design elements ensure that the station works smoothly with any changes in temperature.

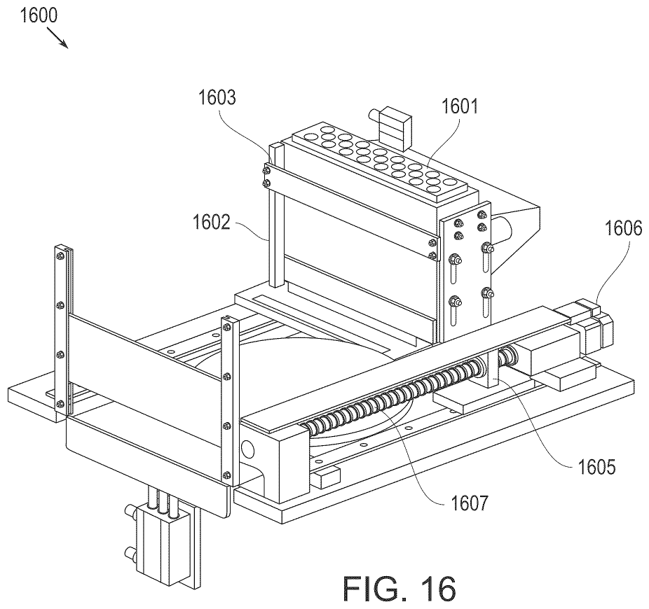

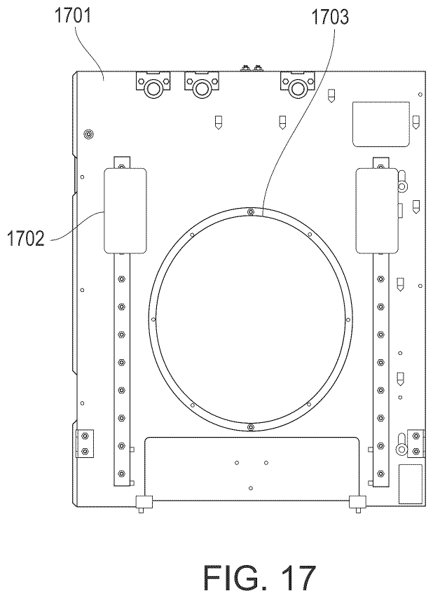

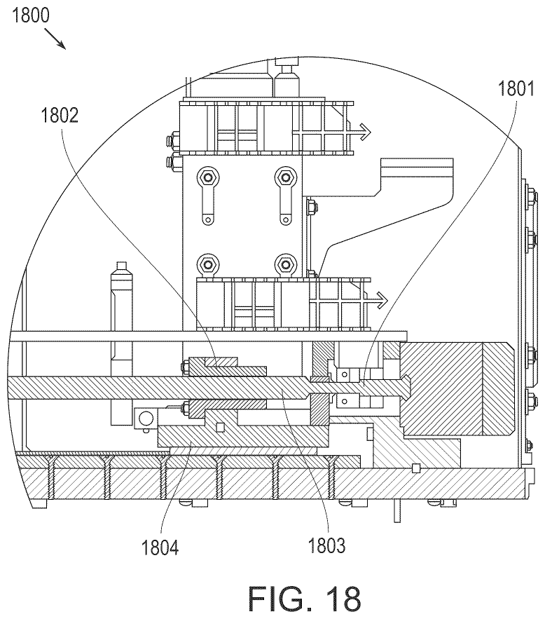

FIG. 16 is a perspective view of the UV head and linear drive within the UV station. The UV head consists of the UV light source 1601, UV supports 1602 and a support bracket 1603. In the station, the wafer is in a fixed position while the head moves above the wafer through the linear drive mechanism 1605. In the depicted embodiment, the linear drive mechanism 1605 includes a servo motor 1606 and a ball screw 1607. FIG. 17 is a top plan view showing the UV head linear drive and a wafer. In FIG. 17, the UV station sits on a chamber plate 1701. A linear slide 1702 and wafer fixed position 1703 are outlined. FIG. 18 is an enlarged side view of a UV head flex joint 1800. The flex joint couples 1801 the servo motor that runs a ball screw for the drive mechanism. A nut 1802 for the screw 1803 is fixed to a perpendicular platform 1804. The rotational energy from the ball screw translates into a sliding motion on the dual rails of the linear drive.

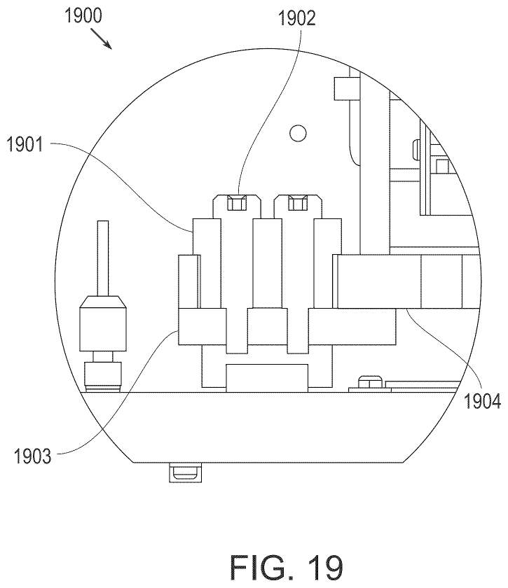

FIG. 19 is a side view of assembly 1900 for mitigating issues from the expansion of the UV light Source slide rail. The linear Due to the significant heat due to radiation exposure within the UV station, the UV framework incorporates an expansion device that allows thermal expansion and contraction within the moving components of the sliding mechanism. The assembly 1900 also provides support and guidance for the linear rail that moves at speeds up to 7 inches per second. The sliding assembly 1900 includes two high precision tolerance rails that run in parallel. The slides on the right rail in FIG. 19 are fixed directly to a brace 1901 that spans both rails. The slides on the left rail are fastened to a rail block 1902 that supports the spanning brace 1901 that rests on top of it. A compression block 1903 is placed on top of the brace 1901 and is fastened by two shoulder screws 1904 into the rail block 1902 which allows for an expansion motion. This expansion assembly aims to mitigate binding of the bearings between both rails.

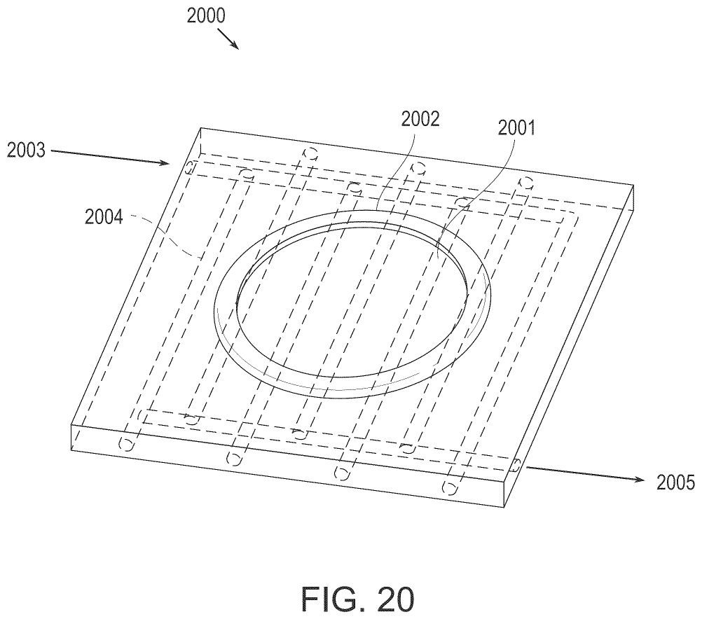

FIG. 20 is a schematic plan view showing a cooling plate 2000 on which a wafer 2001 is placed via a chuck 2002 that holds the wafer directly in contact with the cooling plate. Inclusion of the chuck setup provides numerous benefits including boosting throughput through freeing up the handler, increasing safety through a sealed station that prevents UV escape and limiting temperature increase through an actively cooled or heat sink style chuck. The cooling plate 2000 has a cooling fluid inlet 2003 and utilizes internal channels e.g., 2004 through which chilled water or coolant can flow through to conduct heat from the UV process out of the chamber through a fluid exit 2005. The fluid is cooled by an external radiator or cooling system (not shown). The cooling fluid inlet is kept near or below ambient temperature (e.g., 20 C). The temperature maintains the substrate within the thermal budget (e.g., max temperature in the 50-70 C range) as the process requires to avoid damaging effects of wafer overheating.

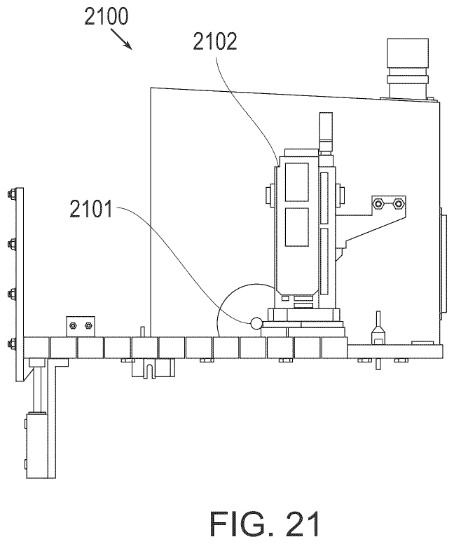

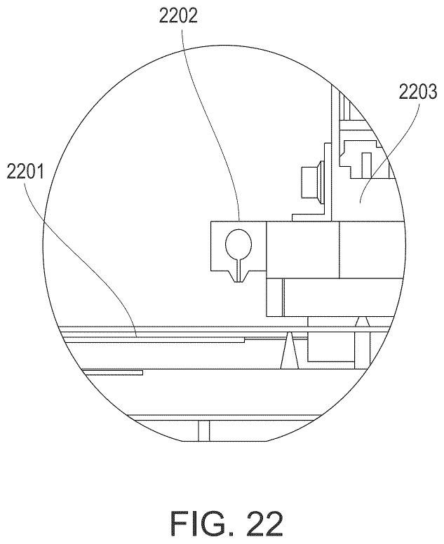

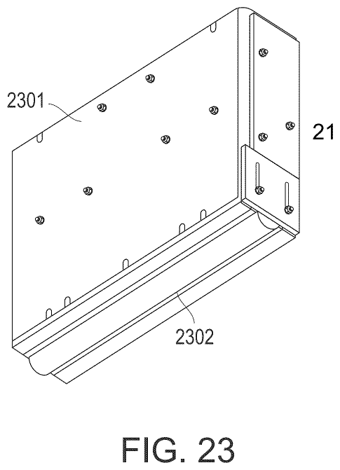

FIG. 21 is a side cross-sectional view of an active cooling assembly 2100 which includes an air knife 2101 positioned on the UV head 2102. The air knife 2101 blows clean dry air (CDA) nitrogen (N₂) directly onto the substrate surface to enhance cooling of the wafer surface. FIG. 22 is an enlarged view of a section of the air knife shown in FIG. 21 and more clearly depicts and embodiment of the air knife location 2201, the wafer 2202 and the UV head 2203.

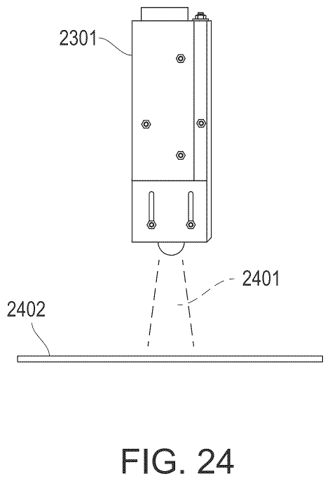

FIG. 23 is a perspective view of an embodiment of a UV radiation unit 2301. The UV radiation unit 2301 includes a convex optical lens 2302 that is used to collimate the UV light produced by the unit. FIG. 24 is a schematic view of a UV head 2301 applying a concentrated dose of radiation 2401 onto to a focused area of a wafer 2402. In operation, the UV head 2301 is traversed back and forth over the substrate surface applying a uniform, controlled dose of collimated UV radiation.

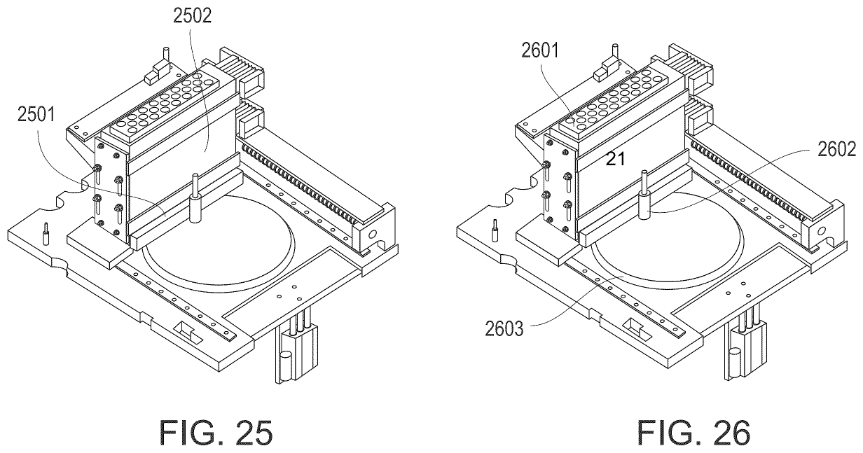

FIG. 25 is a perspective view of a UV light source showing an implementation of light shutters 2501 that are used to block light from potentially bleeding out from around the UV light source 2502. Although the collimator reduces the amount of stray radiation, the shutters 2501 reduce the amount of non-perpendicular radiation that escapes above the UV mount beam. This is important because otherwise part of the wafer can be exposed early, affecting the targeted dose. FIG. 26 is a similar perspective view of the UV light source that illustrates substrate temperature monitoring capability via a real time temperature transmitter 2601 positioned at the center line of the wafer. The temperature transmitter 2601 can be implemented as an infrared unit located on the UV head 2602 and it continuously passes the temperature of the wafer 2603 to control software. The thermal history of the wafer during processing is captured and logged by the control software. The temperature is employed via one or more AI algorithms to ensure that the thermal budget is not exceeded.

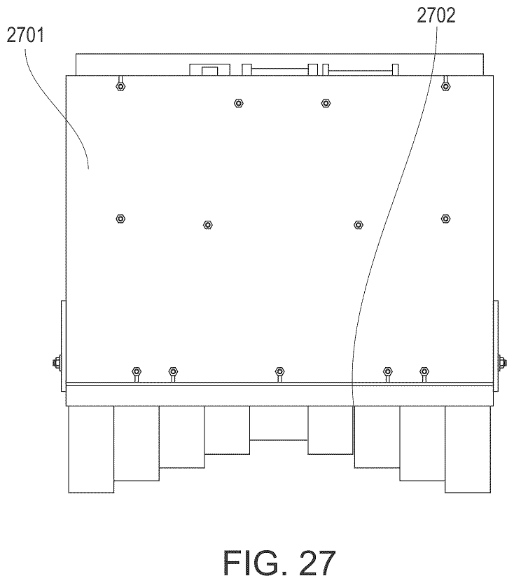

FIG. 27 is a schematic illustration of a mechanism for UV dose control. In this embodiment, The UV head 2701 includes a linear array of light emitting diodes (LEDs) 2702. The power supplied to each LED is controlled via software on a recipe basis to globally control exposure rate, which influences temperature rise. In addition, individual LED output from units can vary based on manufacture or age. Accordingly, these units can also be adjusted individually to control exposure uniformity. For example, the individual LEDs can be controlled to provide a higher exposure rate on LEDs positioned toward the ends of the array in comparison to the center of the array. This control scheme is particularly suited for implementations in which the wafer is rotated to ensure that the center of the wafer, which does not rotate, is not overexposed in comparison to the outer edges of the wafer.

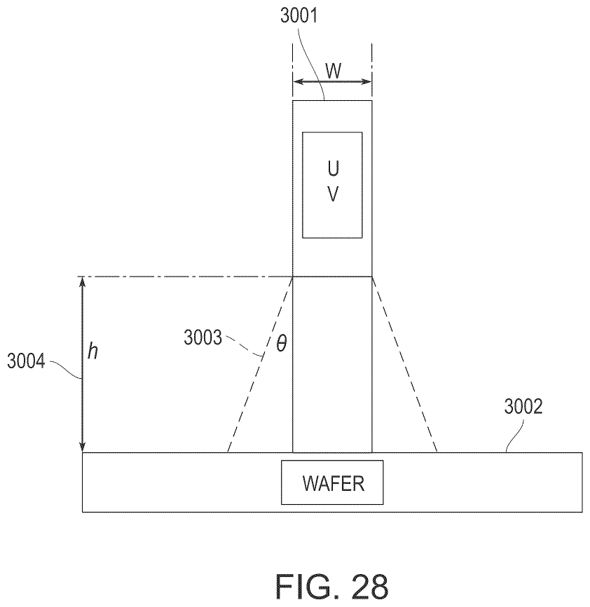

FIG. 28 is a schematic diagram illustrating aspects of UV dose control. A given process recipe contains key parameters, such as the setpoint for the UV exposure dose, which can be in Joules per unit area (square centimeters for example). The recipe can contain another parameter for the thermal budget (e.g., the maximum temperature the wafer may reach during exposure). Control software calculates and controls operation of the UV system to ensure uniformity and dosage level to the substrate. Dose control can be based upon the UV light emitted from the head and the percentage of radiation that actually contacts the wafer. The physical dimensions of the UV head include emitter width (w) and length (l) (in square millimeters, for example). Recipe parameters can include the power setpoint (p) in Watts, the scan speed (v) in mm/s, the substrate diameter (d) (e.g., 300 mm), the UV dose (Σ) in J\mm2 and the thermal budget T max in degrees C.

Control software calculates the exposure time required to deliver the target dosage. The area of the wafers is calculated based on A=π(d\hat{ }2/4), and exposure time in seconds t=(UV dose per unit area) (Area)/power applied, or t=ΣA/p. The time is then converted into the number of scans required (in practice this needs to be an integer). Number of scans n=(tv/d) (integer). Using an integer, the dosage may be slightly off. The time for n scans, the total time taken is t_total=dn/v s. To ensure the exact dosage is delivered, the power p can be adjusted by the ratio of the calculated time required t to the integer scanned time total (t-total), or P_applied=p t\t_total. Since the LEDs are run for all of that time, the energy emitted (J) by the LEDs, Q=dnP_applied/v (Joules).

It is preferred if the maximum wafer temperature (thermal budget) T does not exceed 65 C (T max=65 C). Since the wafer enters at ambient temperature, let us say that a wafer temperature of 65 C is associated with a 40 C rise above ambient. In this case, the energy input is therefore controlled to limit the temperature rise to 40 C. It is noted that this adiabatic process evaluation assumes all energy supplied to the LED UV source converts to heat and no cooling occurs. As noted previously, the thermocouple that measures the temperature on the wafer also provides real time temperature monitoring and alarm capability. The energy Q required to heat the substrate equals the mass of the substrate times its heat capacity, or Q=Cm·dT, in which C is the specific heat capacity of the wafer, m=mass of wafer. dT is set at <40 C. Accordingly, dnP/v <40 Cm. C and m are known quantities. The control software therefore compares the energy input Q=dnP_applied/v J and if this exceeds Q=Cm·dT an alarm is generated and transmitted when there is excess heat creation that can potentially raise the substrate temperature above its maximum setpoint.

In other embodiments, the control software adds factors to the above calculations. When cooling technologies such as the liquid and air cooling apparatus discussed above are used in the UV station, the process is no longer adiabatic. As per above, make up air at ambient temperature flows through the station and is exhausted. An air knife directs ambient air or nitrogen on the wafer surface for cooling. The wafer sits on a chuck embedded in a cooling state in which fluids provide cooling to the wafer. Furthermore, there is typically less than a 100% conversion of radiation energy into heat generation, as the initial model is built upon. The heat generated is dependent on multiple factors including the height of the UV source above the wafer. Since multiple devices can supply cooling, the software includes a mode in which the software control changes UV light source distance and sets applied power to the UV radiation source to extend the time required to apply the reduced UV dose. This both decreases the rate of heat generation and extends the time cooling technologies can remove heat during a cycle.

Returning again to FIG. 28, an area correction factor can also be incorporated. The area of the UV head 3001 is not the same as the area of the wafer 3002. The light from the UV head does not cover all of the wafer all of the time. A correction factor is employed based on the ratio of the area of the wafer to the area received UV light from the UV head. There may also be some loss of energy at the edge of the light beam. The light intensity falls under a Gaussian style distribution, which is approximated here by the dispersion angle (θ) 3003. The peak power of the distribution as observed on the wafer also varies with the height 3004 of the LED UV head above the wafer. Experiments have shown some evidence that this can be modeled by a multiplicative factor correction factor as well.

Some of the processes described herein can be controlled using one or more electronic or computing devices (e.g., electronic control units, processor, etc.). Each such device typically includes a control unit or processor (or multiple processors) that executes program instructions or modules stored in a memory or other non-transitory computer-readable storage medium or device (e.g., solid state storage devices, disk drives, etc.). The various functions disclosed herein may be embodied in such program instructions, or may be implemented in application-specific circuitry (e.g., ASICs or FPGAs). The methods described in connection with the embodiments disclosed herein can be embodied directly in hardware, in a software module executed by a processor device, or in a combination of the two. A software module can reside in RAM memory, flash memory, ROM memory, EPROM memory, EEPROM memory, registers, hard disk, a removable disk, a CD-ROM, or any other form of a non-transitory computer-readable storage medium.

It is to be understood that any structural and functional details disclosed herein are not to be interpreted as limiting the systems and methods, but rather are provided as a representative embodiment and/or arrangement for teaching one skilled in the art one or more ways to implement the methods.

It is to be further understood that like numerals in the drawings represent like elements through the several figures, and that not all components and/or steps described and illustrated with reference to the figures are required for all embodiments or arrangements.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to a viewer. Accordingly, no limitations are implied or to be inferred.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

While the disclosure has been described with reference to exemplary embodiments, it will be understood by those skilled in the art that various changes may be made and equivalents may be substituted for elements thereof without departing from the scope of the disclosed invention. In addition, many modifications will be appreciated by those skilled in the art to adapt a particular instrument, situation or material to the teachings of the disclosure without departing from the essential scope thereof. Therefore, it is intended that the invention not be limited to the particular embodiment disclosed as the best mode contemplated for carrying out this invention, but that the invention includes all embodiments falling within the scope of the appended claims.

What is claimed is:

1. A UV-assisted system for stripping a photoresist from a semiconductor substrate, the system comprising:
an ultraviolet (UV) exposure station (“UV station”) having a UV radiation source and a UV controller, the UV station being adapted to receive the substrate and to apply UV radiation over an entire surface of the substrate, the UV radiation changing material properties of the photoresist as to increasing solubility and loosening bonding of the photoresist to the substrate; and
at least one additional wet process station adapted to receive the substrate after exposure to UV in the UV station and to remove the exposed photoresist from the substrate.

2. The UV-assisted system of claim 1, wherein the at least one additional station includes a wet chemistry immersion station in which the substrate with loosened photoresist is immersion in a solvent bath which causes removal of the exposed photoresist material.

3. The UV-assisted system of claim 2, wherein the at least one additional station further includes a spray station adapted to receive the substrate after being processed in the immersion station, the spray station having a solvent sprayer adapted to spray the substrate to remove residual photoresist or residues from the substrate after removal of the photoresist in the immersion station.

4. The UV-assisted system of claim 3, wherein the at least one additional station further includes a spin-dry-rinse (SDR) station adapted to receive the substrate after being processed in the spray station, the SDR station being adapted to remove any remaining solvent, or other residues left on the substrate from previous processing.

5. The UV-assisted system of claim 1, wherein the UV controller is configured to control the UV source to radiate for a selected dosage setpoint.

6. The UV-assisted system of claim 1, wherein the UV controller prevents a temperature of the substrate from exceeding a set maximum value by adjusting at least one of a power dosage emitted by the UV source, an amount of time that UV radiation is delivered to the substrate, a number of movement passes made by the substrate through the UV station, and a speed of the substrate during movement through the UV station.

7. The UV-assisted system of claim of claim 6, further comprising an inlet in the UV station for receiving clean dry air (CDA) or N₂ for cooling the UV station.

8. The UV-assisted system of claim 1, further comprising a UV dosage measurement device, wherein the UV dosage measurement device is configured to provide data to the UV controller, and the UV controller is further configured to determine whether a total amount of UV radiation received by the substrate is within a threshold of a setpoint maximum value.

9. The UV-assisted system of claim 3, further comprising an immersion station controller and a spray station controller, wherein the immersion station is configured to control an amount of time that the substrate is processed in the immersion station and the spray station controller is configured to control an amount of time the substrate is processed in the spray station, wherein the immersion station control and spray station controller control respective processing times based on a UV dosage to which the substrate is exposed in the UV station.

10. The UV-assisted system of claim 3, wherein the solvent used in the immersion chamber and the spray chamber includes a diluted base.

11. The UV-assisted system of claim 1, wherein exposure of the substrate carrying photoresist to a suitable dosage of UV radiation improves removal of residual organic debris and reduces usage of chemicals, cycle time and hazardous waste creation.

12. A UV-assisted method for stripping a photoresist from a semiconductor substrate, the method comprising:
exposing an entire surface of the substrate to a dose of UV radiation, the UV radiation changing material properties of the photoresist and loosening bonding of the photoresist to the substrate; and
processing the substrate using wet chemistry to remove the loosened photoresist from the substrate.

13. The UV-assisted method of claim 12, wherein processing the substrate using wet chemistry includes:
immersing the substrate in a solvent bath for a selected amount of time which causes removal of the loosened photoresist material;
spraying the substrate after immersion to remove residual photoresist or residues from the substrate after removal of the photoresist by immersion;
spinning the substrate;
rinsing the substrate and
drying the substrate,
wherein the spinning, rinsing and drying removes any remaining solvent, or other residues left on the substrate from previous processing.

14. The UV-assisted method of claim 12, further comprising controlling the dose of UV radiation to a selected dosage setpoint.

15. The UV-assisted method of claim 14, further comprising controlling a temperature of the substrate by adjusting at least one of: the dosage of UV; an amount of time that UV radiation is delivered to the substrate, and a number of movement passes made by the substrate past a source of UV radiation.

16. The UV assisted system of claim 1, further comprising a collimator coupled to the UV radiation source that focuses radiation emitted from the radiation source into a beam path this is perpendicular to the substrate orientation.

17. The UV assisted system of claim 1, further comprising a thermocouple or temperature transmitter that provides real time data to the UV controller for tracking the temperature of the substrate.

18. The UV assisted system of claim 1, wherein the UV controller is configured to logs temperature data received from the thermocouple or transmitter and to output alarms when a maximal thermal budget is exceeded.

19. The UV assisted system of claim 17, wherein in the UV controller is configured to receive data from the thermocouple or temperature transmitter that is tracking the temperature of the substrate and to modify process control variables to maintain a maximum temperature below the thermal budget setpoint based on the real time temperature data.

20. The UV assisted system of claim 19, wherein the process control variables includes at least one of power delivered to the UV radiation source, a distance between the UV radiation source and the substrate, arm scan speed, active cooling parameters, air knife flow rate, and exhaust flow rate.
